(19) United States
(12) Patent Application Publication
(10) Pub. No.: US 2013/0083577 A1
(43) Pub. Date: Apr. 4, 2013

(54) OFFLINE LOW VOLTAGE DC OUTPUT CIRCUIT WITH INTEGRATED FULL BRIDGE RECTIFIERS

(71) Applicant: Joseph Urienza, Milpitas, CA (US)

(72) Inventor: Joseph Urienza, Milpitas, CA (US)

(73) Assignee: Monolithic Power Systems, Inc.

(21) Appl. No.: 13/251,067

(22) Filed: Sep. 30, 2011

(51) Int. Cl. H02M 7/21; G06F 17/50; H01L 27/098

(52) U.S. Cl. 363/126; 257/272; 716/119; 257/E27.069

(57) ABSTRACT

The present disclosure discloses an offline low voltage DC output circuit with integrated full bridge rectifiers. The offline low voltage DC output circuit comprises two depletion high voltage pass transistors and a bridge rectifier, wherein most of the voltage is dropped across the pass transistor device. In one embodiment, the offline low voltage DC output circuit further comprises a ballast resistor to minimize substrate injection.

### FIELD

The present disclosure relates to offline integrated circuits, more particularly, the present disclosure relates to offline AC-low voltage full-wave rectified DC output integrated bridge circuits.

### BACKGROUND OF THE DISCLOSURE

Sometimes in low power offline applications, rectified output voltage is needed which may be used to power small logic signal, boot/wake-up startup circuits, transponders, sensor circuits, small relays, etc.

FIG. 1 illustrates a schematic circuit of a prior art offline low voltage rectified DC output circuit 50. The circuit 50 comprises a transformer which receives an input AC voltage, and based on the input AC voltage, the transformer provides a step-down AC voltage; and a bridge which receives the step-down AC voltage, and based on the step-down AC voltage, the bridge rectifier provides a rectified DC output waveform.

However, such circuit 50 needs a transformer to step down the input AC voltage, which highly increases the system volume, weight and cost.

So there is a need to provide a simpler and cost effective integrated circuit (semiconductor approach) of offline AC-low voltage DC rectification.

### SUMMARY

It is an object of the present disclosure to provide a circuit and a method for constant current regulation of power supplies.

In accomplishing the above and other objects, there has been provided, in accordance with an embodiment of the present disclosure, an offline low voltage DC output circuit, comprising: a first input port and a second input port configured to receive an input AC voltage; an output port configured to provide an output voltage; a first depletion high voltage pass transistor coupled to the first input port to receive the input AC voltage, and based on the input AC voltage, the first depletion high voltage pass transistor provides a first voltage; a second depletion high voltage pass transistor coupled to the second input port to receive the input AC voltage, and based on the input AC voltage, the second depletion high voltage pass transistor provides a second voltage; and a bridge rectifier having a first input terminal, a second input terminal, and an output terminal, wherein the first input terminal is coupled to the first depletion high voltage pass transistor to receive the first voltage, the second input terminal is coupled to the second depletion high voltage pass transistor to receive the second voltage, and wherein the output terminal is coupled to the output port.

In addition, there has been provided, in accordance with an embodiment of the present disclosure, an offline low voltage DC output integrated circuit die comprising: a plurality of minority generating devices; a plurality of mergeable NWell; a plurality of unmergeable devices: a first site, and a second site, wherein the first site and the second site are placed on opposite sides of the integrated circuit die; an N-well tub between the first site and the second site; and a die seal; wherein the minority generating devices are placed at the first site and the second site; the devices with mergeable NWell are group together and placed in the N-well tub; and the unmergeable devices are placed next to the die seal or close to an edge of the integrated circuit die.

Furthermore, there has been provided, in accordance with an embodiment of the present disclosure, a method for providing a low voltage DC output from an AC offline source, comprising: receiving an AC input voltage; generating a first voltage in response to the AC input voltage; generating a second voltage in response to the AC input voltage; and generating a low voltage DC output by rectifying the first voltage and the second voltage.

These and other features of the present disclosure will be readily apparent to persons of ordinary skill in the art upon reading the entirety of this disclosure, which includes the accompanying drawings and claims.

### BRIEF DESCRIPTION OF THE DRAWINGS

FIG. 1 illustrates a schematic circuit of a prior art offline AC-low voltage rectified DC output circuit 50.

FIG. 2 illustrates a schematic circuit of an offline AC-low voltage rectified DC output circuit 100 in accordance with an embodiment of the present disclosure.

FIG. 3 schematically illustrates the output voltage (V_{O}) and the input AC voltage (AC) in the offline AC-low voltage rectified DC output circuit 100 in FIG. 2.

FIG. 4 schematically illustrates a layout scheme of a typical pass transistor.

FIG. 5 illustrates a schematic circuit of an offline AC-low voltage rectified DC output circuit 200 in accordance with another embodiment of the present disclosure.

FIG. 6 illustrates a schematic circuit of the first depletion high voltage pass transistor 203 and its parallel-coupled diode 51 which is part of the bridge rectifier 205 when there is no ballast resistor.

FIG. 7 illustrates a schematic circuit of the first depletion high voltage pass transistor 203 and its parallel-coupled diode 51 which is part of the bridge rectifier 205 when there is a ballast resistor.

FIG. 8 illustrates a schematic circuit of an offline AC-low voltage rectified DC output circuit 300 in accordance with an embodiment of the present disclosure.

FIGS. 9a and 9b schematically show a die 400 for an offline low voltage DC output circuit in accordance with an embodiment of the present disclosure.

FIG. 10 schematically shows a method 500 for a layout scheme for a die shown in FIGS. 9a and 9b in accordance with an embodiment of the present disclosure.

FIG. 11 schematic shows a flowchart 600 of a method for providing a low voltage DC output from an AC offline source in accordance with an embodiment of the present disclosure.

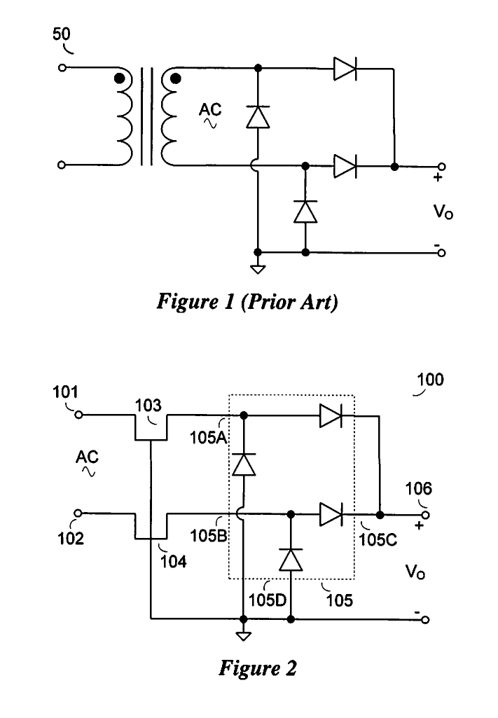

The use of the same reference label in different drawings indicates the same or like components.

### DETAILED DESCRIPTION

Embodiments of circuits for integrated full bridge rectifiers for offline low voltage DC output are described in detail herein. In the following description, some specific details, such as example circuits for these circuit components, are included to provide a thorough understanding of embodiments of the disclosure. One skilled in relevant art will recognize, however, that the disclosure can be practiced without one or more specific details, or with other methods, components, materials, etc.

The following embodiments and aspects are illustrated in conjunction with circuits and methods that are meant to be exemplary and illustrative. In various embodiments, the above problem has been reduced or eliminated, while other embodiments are directed to other improvements.

The present disclosure relates to integrated circuits and methods of offline AC-low voltage DC rectification. These integrated circuits usually comprise of two depletion high voltage pass transistors and bridge rectifiers, wherein most of the voltage is dropped across the pass transistor devices, so that other components in the circuit could be low voltage devices.

FIG. 2 illustrates a schematic circuit of an offline AC-low voltage rectified DC output circuit 100 in accordance with an embodiment of the present disclosure. The offline AC-low voltage rectified DC output circuit 100 comprises a first input port 101 and a second input port 102 configured to receive an input AC signal (AC); an output port 106 configured to provides an output rectified voltage (V_{O}); a first depletion high voltage pass transistor 103 coupled to the first input port 101 to receive the input AC voltage, and based on the input AC voltage, the first depletion high voltage pass transistor 103 provides a first voltage; a second depletion high voltage pass transistor 104 coupled to the second input port 102 to receive the input AC voltage, and based on the input AC voltage, the second depletion high voltage pass transistor 104 provides a second voltage; and a bridge rectifier 105 having a first input terminal 105a, a second input terminal 105b, and an output terminal 105c, wherein the first input terminal 105a is coupled to the first depletion high voltage pass transistor 103 to receive the first voltage, the second input terminal 105b is coupled to the second depletion high voltage pass transistor 104 to receive the second voltage, and the output terminal 105C is coupled to the output port 106.

In one embodiment, the first depletion high voltage pass transistor 103 comprises a first depletion high voltage JFET; and the second depletion high voltage pass transistor 104 comprises a second depletion high voltage JFET.

In one embodiment, the bridge rectifier 105 further comprises a fourth terminal 105D coupled to ground.

In one embodiment, the first depletion high voltage pass transistor 103 and the second depletion high voltage pass transistor 104 each has a gate coupled to ground.

In one embodiment, the bridge rectifier comprises four diodes. The diodes may be Schottky diodes, regular PN diodes or base-collector connected bipolar transistors, which is known to one skilled in the art.

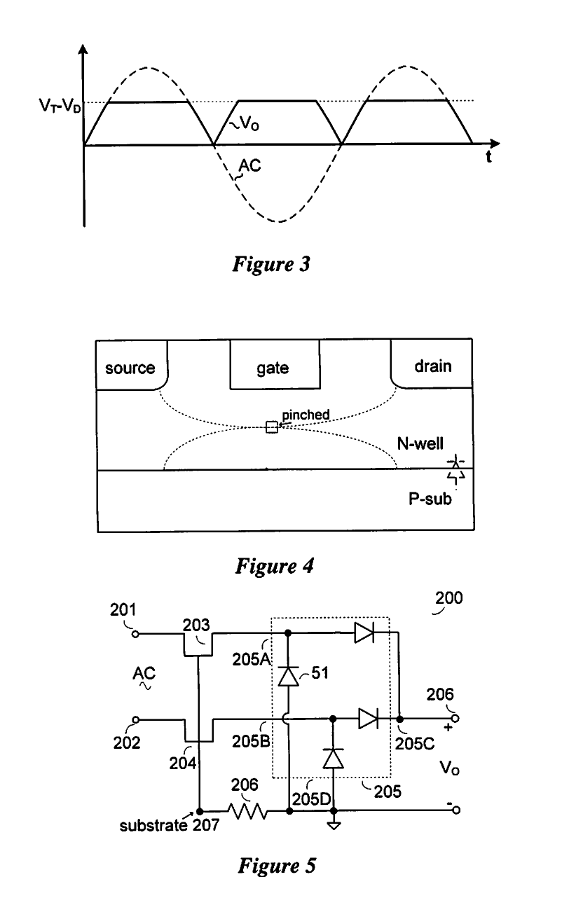

Because the first depletion high voltage pass transistor 103 and the second depletion high voltage pass transistor 104 have conductive channels when their gates are connected to ground, when the absolute value of the input AC voltage is lower than the pinch off voltage (V_{T}) of the depletion high voltage pass transistors, the output voltage (V_{O}) follows the input AC voltage; when the absolute value of the input AC voltage is higher than the pinch off voltage (V_{T}) of the depletion high voltage pass transistors, the voltage at the conjunction of the depletion high voltage pass transistor and the bridge rectifier 105 stays at the pinch off voltage (V_{T}) level of the depletion high voltage pass transistors. As a result, the output voltage (V_{O}) stays at the pinch off voltage (V_{T}) of the depletion high voltage pass transistors minus the diode voltage drop (V_{D}), i.e., V_{O}=V_{T}−V_{d}. FIG. 3 schematically illustrates the clipped full-wave rectified output voltage (V_{O}) and the input AC voltage (AC) in the offline AC-low voltage rectified DC output circuit 100 in FIG. 2.

As illustrated herein before in various embodiments of the present disclosure, the gates of the first depletion high voltage pass transistor 103 and the second depletion high voltage pass transistor 104 are connected to ground, i.e., the substrates of the first depletion high voltage pass transistor 103 and the second depletion high voltage pass transistor 104 are connected to ground. In typical applications, the pass transistor gate comprises a P type substrate (P-sub) as bottom gate and a separate P type implant/diffusion as top gate, while the pass transistor channel is an N type well (N-well), which form a PN junction, as illustrated in FIG. 4. The top gate and the bottom gate would be connected once the N-well is pinched. When the PN junction gets forward biased, minority carriers get injected on both sides (P with an electron minority, and N with a hole minority). Such unintentional minority carriers may disturb sensitive circuits, e.g., causing a latch up or any parametric malfunctions. FIG. 5 illustrates a schematic circuit of an offline low voltage DC output circuit 200 in accordance with an embodiment of the present disclosure which minimizes the “minority injection” or the unintentional generation of minority carriers.

The offline AC-low voltage rectified DC output circuit 200 is similar to the offline AC-low voltage rectified DC output circuit 100. Different to the offline AC-low voltage rectified DC output circuit 100 in FIG. 2, the offline AC-low voltage rectified DC output circuit 200 in FIG. 5 further comprises a ballast resistor 206 coupled between a substrate 207 and ground.

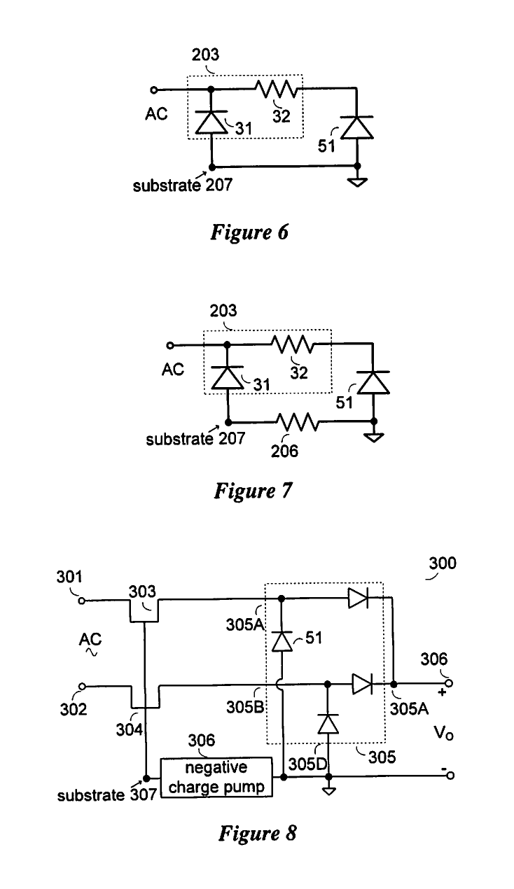

The operation of the offline AC-low voltage rectified DC output circuit 200 is described by referring to FIG. 6 and FIG. 7.

FIG. 6 illustrates a schematic circuit representation of the first depletion high voltage pass transistor 203 and its parallel-coupled diode 51 which is part of the bridge rectifier 205 when there is no ballast resistor 206. The first depletion high voltage pass transistor 203 comprises a diode 31 and an N-well channel resistor 32 connected as shown. As shown in FIG. 4, the N-well channel resistor 32 is coupled in series with the diode 51 between the input AC voltage and ground, while the diode 31 is coupled between the input AC voltage and ground. Since the diode 31 introduces less resistance to current flow, more current flows through the diode 31 than through the diode 51. Allowing the diode 31 to get forward biased introduces substrate injection. The more current flow through the diode 31, the more injection occurs. In addition, other circuits in the same die may also get interfered.

FIG. 7 illustrates a schematic circuit representation of the first depletion high voltage pass transistor 203 and its parallel-coupled diode 51 which is part of the bridge rectifier 205 when there is a ballast resistor 206. As illustrated hereinbefore, the first depletion high voltage pass transistor 203 comprises the diode 31 and the n-well channel resistor 32 connected as shown. As shown in FIG. 5, the N-well channel resistor 32 is coupled in series with the diode 51 between the input AC voltage and ground, while the diode 31 is coupled in series with the ballast resistor 206 between the input AC voltage and ground. The ballast resistor 206 discourages the current flow through the diode 31, thus minimizing the amount of injection.

The operation of other parts in the offline AC-low voltage rectified DC output circuit 200 is similar to that of the offline AC-low voltage rectified DC output circuit 100.

In one embodiment, the ballast resistor may be a parasitic resistor or a defined resistor, e.g. implant resistor, diffusion resistor, poly silicon resistor, etc. . . . .

In one embodiment, the ballast resistor may be replaced by active circuits such as a charge pump circuit. FIG. 8 illustrates a schematic circuit of an offline AC-low voltage rectified DC output circuit 300 in accordance with an embodiment of the present disclosure. The offline AC-low voltage rectified DC output circuit 300 is similar to the offline AC-low voltage rectified DC output circuit 200. Different to the offline AC-low voltage rectified DC output circuit 200 in FIG. 5, the offline AC-low voltage rectified DC output circuit 300 in FIG. 8 comprises a negative charge pump 306 coupled between a substrate 307 and the ground instead of the ballast resistor 206.

In one embodiment, all other circuits are placed in an N-well tub so that the substrate is fully the pass transistor body and not sharing with other devices of other circuits. The negative voltage charge pump applies a reverse bias at the pass transistor p body and N-well channel so that no current flows through.

The operation of other parts in the offline AC-low voltage rectified DC output circuit 300 is similar to that of the offline AC-low voltage rectified DC output circuit 100.

As illustrated hereinbefore, there are two high voltage structures in the offline low voltage DC output circuit 100/200/300, which may be integrated into a chip in one embodiment. As a result, the die area of the offline low voltage DC output circuit 100/200/300 is highly reduced, which further reduces the cost.

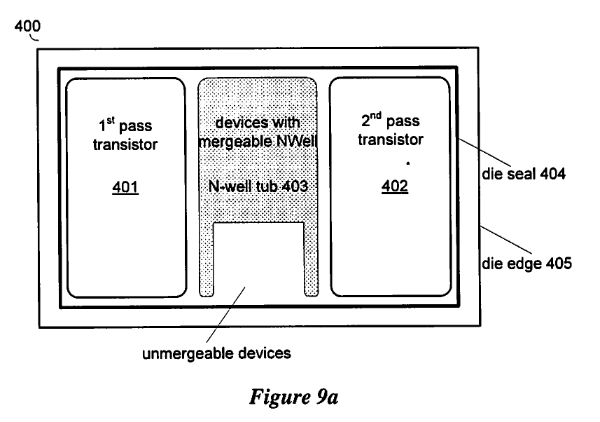

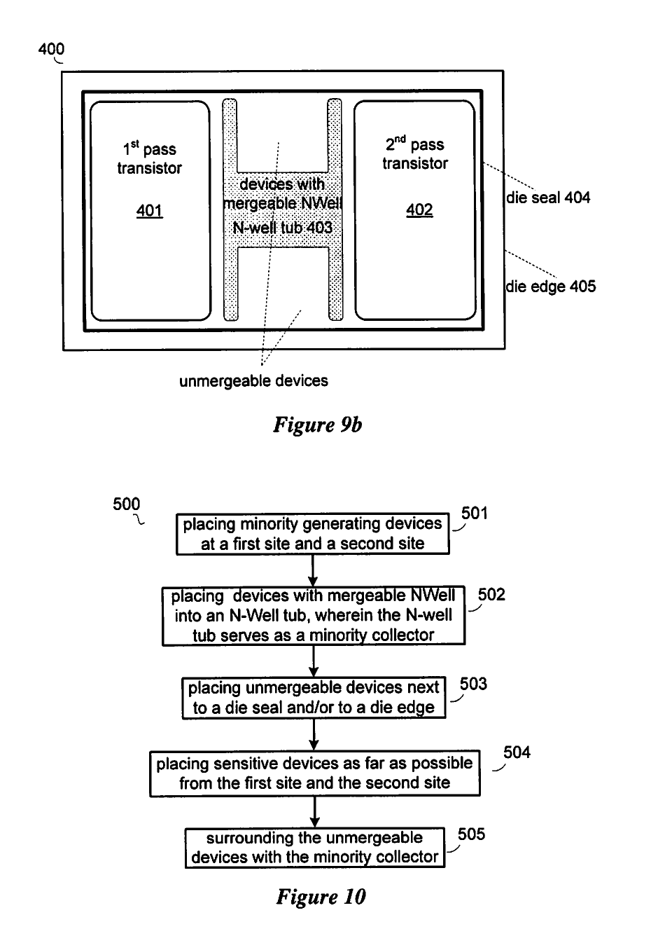

The effect of any generated minority carriers may also be alleviated by layout techniques. FIGS. 9a and 9b schematically show the top view of a die 400 for an integrated offline low voltage DC output circuit in accordance with an embodiment of the present disclosure. The integrated offline low voltage DC output circuit comprises a plurality of minority generating devices, a plurality of devices with mergeable NWell, and a plurality of unmergeable devices, wherein devices with mergeable NWell comprises devices whose NWell is at same potential as NWell tub, and unmergeable devices comprise devices whose NWell is at potential different from NWell tub, non-floating devices (e.g., diodes, bipolar, etc. . . . ). In the example of FIGS. 9a and 9b, the die 400 comprises: a first site 401, and a second site 402, wherein the first site 401 and the second site 402 are placed on opposite sides of the die to make their separation distance the farthest possible; an N-well tub 403 between the first site 401 and the second site 402, wherein the N-well tub 403 serves as a huge minority collector; and a die seal 404; wherein the minority generating devices are placed at the first site 401 and the second site 402; the devices with mergeable NWell are group together and placed in the N-well tub 403; and the unmergeable devices are placed next to the die seal 404 and/or close to an die edge 405 of the die.

In one embodiment, the N-well tub 403 serves as a minority collector. In one embodiment, the minority collector is coupled to a potential reference.

In one embodiment, the minority generating devices comprise a first depletion high voltage pass transistor and a second depletion high voltage pass transistor.

In one embodiment, the potential reference is ground.

In one embodiment, the N-well tub 403 comprises one opening next to the die seal (and/or close to die edge) to surround unmergeable devices, as shown in FIG. 9a.

In other embodiments, the N-well tub 403 may comprise more than one opening, e.g. 2 openings to surround unmergeable devices if there are too many unmergeable devices, as shown in FIG. 9b.

As illustrated above, devices with mergeable NWell are placed in the N type well 403, and unmergeable devices are placed next to the die seal 404 (and/or close to die edge 405) surrounded with the minority collector, so the die seal and/or the die edge 405 may take some of the wandering minority carriers and minimize the number of carriers from reaching the sensitive devices.

FIG. 10 schematically shows a method 500 for a layout scheme for an integrated circuit die shown in FIGS. 9a and 9b in accordance with an embodiment of the present disclosure. The method comprises:

Step 501, placing minority generating devices at a first site and a second site; wherein the first site and the second site are placed on opposite sides of the integrated circuit die;

Step 502, placing devices with mergeable NWell into an N-Well tub, wherein the N-well tub serves as a minority collector;

Step 503, placing unmergeable devices next to a die seal and/or close to a die edge;

Step 504, placing sensitive devices as far as possible from the first site and the second site; and

Step 505, surrounding unmergeable devices with the minority collector.

In one embodiment, the minority generating devices comprise a first depletion high voltage pass transistor and a second depletion high voltage pass transistor.

In one embodiment, the minority collector comprises NWell tubs. An optional N-type buried layer (NBL) on this NWell tub further enhances the collection area.

In one embodiment, sensitive devices comprise diffusion devices which may be affected by minority carriers.

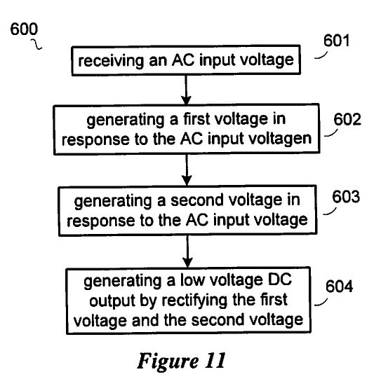

FIG. 11 schematically shows a flowchart 600 of a method for providing a low voltage DC output from an AC offline source in accordance with an embodiment of the present disclosure. The method comprises:

Step 601, receiving an AC input voltage;

Step 602, generating a first voltage in response to the AC input voltage;

Step 603, generating a second voltage in response to the AC input voltage; and

Step 604, generating a low voltage DC output by rectifying the first voltage and the second voltage.

In one embodiment, in step 602, the first voltage is generated by a first depletion pass transistor; and in step 603, the second voltage is generated by a second depletion pass transistor.

In one embodiment, in step 604, the rectifying is executed by a bridge rectifier.

In one embodiment, both the first depletion pass transistor and the second depletion pass transistor have a gate connected to ground, respectively.

In one embodiment, both the first depletion pass transistor and the second depletion pass transistor have a substrate connected to ground via a ballast resistor, respectively.

In one embodiment, both the first depletion pass transistor and the second depletion pass transistor have a substrate connected to ground via an active circuit.

In one embodiment, the active Circuit comprises a charge pump.

This written description uses examples to disclose the disclosure, including the best mode, and also to enable a person skilled in the art to make and use the disclosure. The patentable scope of the disclosure may include other examples that occur to those skilled in the art.

I/we claim:

1. An offline low voltage DC output circuit, comprising:
a first input port and a second input port configured to receive an input AC voltage;
an output port configured to provide an output voltage;
a first depletion high voltage pass transistor coupled to the first input port to receive the input AC voltage, and based on the input AC voltage, the first depletion high voltage pass transistor provides a first voltage;
a second depletion high voltage pass transistor coupled to the second input port to receive the input AC voltage, and based on the input AC voltage, the second depletion high voltage pass transistor provides a second voltage; and
a bridge rectifier having a first input terminal, a second input terminal, and an output terminal, wherein the first input terminal is coupled to the first depletion high voltage pass transistor to receive the first voltage, the second input terminal is coupled to the second depletion high voltage pass transistor to receive the second voltage, and wherein the output terminal is coupled to the output port.

2. The offline low voltage DC output circuit of claim 1, wherein the first depletion high voltage pass transistor and the second depletion high voltage pass transistor each having a gate coupled to ground.

3. The offline low voltage DC output circuit of claim 1, wherein the first depletion high voltage pass transistor and the second depletion high voltage pass transistor each having a substrate coupled to ground via a ballast resistor.

4. The offline low voltage DC output circuit of claim 3, wherein the ballast resistor comprises a poly resistor or any non-diffusion type resistor.

5. The offline low voltage DC output circuit of claim 1, wherein the first depletion high voltage pass transistor comprises a first depletion high voltage JFET; and the second depletion high voltage pass transistor comprises a second depletion high voltage JFET.

6. The offline low voltage DC output circuit of claim 1, wherein the first depletion high voltage pass transistor and the second depletion high voltage pass transistor each having a substrate coupled to ground via an active circuit.

7. The offline low voltage DC output circuit of claim 6, wherein the active circuit comprises a negative charge pump.

8. The offline low voltage DC output circuit of claim 1, wherein the bridge rectifier further comprises a fourth terminal coupled to ground.

9. An offline low voltage DC output integrated circuit die comprising:
a plurality of minority generating devices;
a plurality of mergeable NWell;
a plurality of unmergeable devices:
a first site, and a second site, wherein the first site and the second site are placed on opposite sides of the integrated circuit die;
an N-well tub between the first site and the second site; and
a die seal; wherein
the minority generating devices are placed at the first site and the second site;
the devices with mergeable NWell are group together and placed in the N-well tub; and
the unmergeable devices are placed next to the die seal or close to an edge of the integrated circuit die.

10. The integrated circuit die of claim 9, wherein the N-well tub serves as a minority collector; and the edge of the integrated circuit die serves as a recombination site for minority carriers.

11. The integrated circuit die of claim 10, wherein the minority collector further comprises a N-type buried layer.

12. The integrated circuit die of claim 9, wherein the minority generating devices comprise a first depletion high voltage pass transistor and a second depletion high voltage pass transistor.

13. A method for a layout scheme for the integrated circuit die as claimed in claim 9, characterized that the method comprises:
placing minority generating devices at a first site and a second site; wherein the first site and the second site are placed on opposite sides of the integrated circuit die;
placing devices with mergeable NWell into a N-Well tub, wherein the N-well tub serves as a minority collector;
placing unmergeable devices next to a die seal or close to a die edge;
placing sensitive devices as far as possible from the first site and the second site; and
surrounding unmergeable devices with the minority collector.

14. The integrated circuit die of claim 12, wherein the minority generating devices comprise a first depletion high voltage pass transistor and a second depletion high voltage pass transistor.

15. A method for providing a low voltage DC output from an AC offline source, comprising:
receiving an AC input voltage;
generating a first voltage in response to the AC input voltage;
generating a second voltage in response to the AC input voltage; and
generating a low voltage DC output by rectifying the first voltage and the second voltage.

16. The method of claim 15, wherein the rectifying is executed by a bridge rectifier.

17. The method of claim 15, wherein
the first voltage is generated by a first depletion pass transistor; and
the second voltage is generated by a second depletion pass transistor.

18. The method of claim 15, wherein both the first depletion pass transistor and the second depletion pass transistor have a substrate connected to ground via a ballast resistor.

19. The method of claim 15, wherein both the first depletion pass transistor and the second depletion pass transistor have a substrate connected to ground via an active circuit.

20. The method of claim 19, wherein the active circuit comprises a charge pump.
